(19) United States
(12) Patent Application Publication
(10) Pub. No.: US 2026/0313839 A1
(43) Pub. Date: Oct. 8, 2026

(54) Electronic Circuit Board and Immersion Cooling Apparatus for the Same

(71) Applicant: SK Innovation Co., Ltd., Seoul (KR)

(72) Inventors: Ja Cheol KOO, Daejeon (KR); Byung Soo KIM, Daejeon (KR); Hong Chan KIM, Daejeon (KR); Wan Ju JEONG, Daejeon (KR); June Ho CHO, Daejeon (KR)

(21) Appl. No.: 19/639,549

(22) Filed: Apr. 6, 2026

(30) Foreign Application Priority Data
Apr. 7, 2025 (KR) 10-2025-0044991

(51) Int. Cl. H05K 7/20

(52) U.S. Cl. CPC H05K 7/203; H05K 7/20327

(57) ABSTRACT

An immersion cooling apparatus comprises a housing configured to store a coolant; a plurality of electronic circuit boards disposed inside the housing and positioned to be immersed in the coolant; and a heat exchange device in fluid connection with the housing and configured to remove heat absorbed by the coolant from the plurality of electronic circuit boards. At least one of the plurality of electronic circuit boards comprises a substrate; a plurality of electronic components mounted on the substrate; and at least one coalescing unit disposed on the substrate between two electronic components of the plurality of electronic components, the at least one coalescing unit configured to intercept and coalesce a plurality of first vapor bubbles generated by heating of the coolant proximate to the plurality of electronic components into a second vapor bubble having a size greater than each of the plurality of first vapor bubbles.

### CROSS-REFERENCE TO RELATED APPLICATION

This application claims priority to Korean Patent Application No. 10-2025-0044991 filed Apr. 7, 2025, the disclosure of which is incorporated herein by reference in its entirety.

### BACKGROUND

### Technical Field

The present disclosure relates to an electronic circuit board and an immersion cooling apparatus for the same.

### Technical Considerations

With the advancement of cutting-edge technologies such as the Internet of Things (IoT), Artificial Intelligence (AI), 5th Generation (5G) mobile communication, and streaming technology, the development of high-performance chips (e.g., integrated circuits (ICs)) is accelerating. While such high-performance chips feature high integration density and processing speeds to improve computing power, they also face the problem of increased heat generation. For example, in a high-density chip structure, heat dissipation is restricted, causing overheating problems, which can lead to degradation of system performance and stability.

Immersion cooling technology has recently gained increasing attention as a solution to the heat generation problem of high-performance chips. This technology can efficiently remove heat by immersing a substrate (such as a circuit board), on which high-performance chips are mounted, in a non-conductive cooling fluid (e.g., dielectric fluid or dielectric coolant).

However, during immersion cooling, the cooling fluid that has absorbed heat from a lower-positioned electronic components may rise and degrade heat removal efficiency of higher-positioned electronic components. For instance, when a plurality of substrates are immersed in the coolant adjacent to each other (e.g., spaced apart by a preselected interval), vapor bubbles generated on one substrate may adhere (or accumulate) to a surface of a substrate as the vapor bubbles rises and form vapor pockets or a thin vapor film and degrade heat dissipation performance. Consequently, the cooling efficiency of the immersion cooling apparatus may be reduced.

### SUMMARY

Embodiments of the present disclosure may provide an electronic circuit board and an immersion cooling apparatus therefore, capable of improving cooling efficiency.

According to an embodiment of the present disclosure, there is provided an immersion cooling apparatus, the apparatus comprising: a housing configured to store a coolant (e.g., a dielectric coolant); a plurality of electronic circuit boards disposed inside the housing and positioned to be immersed in the coolant; and a heat exchange device in fluid connection with the housing and configured to remove heat absorbed by the coolant from the plurality of electronic circuit boards. At least one of the plurality of electronic circuit boards comprises: a substrate; a plurality of electronic components mounted on the substrate; and at least one coalescing unit disposed on the substrate between two electronic components of the plurality of electronic components, wherein the at least one coalescing unit configured to intercept and coalesce a plurality of first vapor bubbles generated by heating of the coolant proximal to the plurality of electronic components into a second vapor bubble having a size greater than each of the plurality of first vapor bubbles.

In some non-limiting embodiments, the at least one second vapor bubble detaches from the at least one coalescing unit when a buoyant force acting on the at least one second vapor bubble exceeds an adhesive force between the at least one second vapor bubble and the at least one coalescing unit. In one embodiment, the buoyant force of the at least one second vapor bubble exceeds an adhesive force between the at least one second vapor bubble and an adjacent substrate such that the at least one second vapor bubble does not adhere to the adjacent substrate upon contact therewith.

In some non-limiting embodiments, the plurality of electronic circuit boards are arranged within the housing at a mounting angle relative to the bottom surface of the housing. The mounting angle may be selected based on at least one of length of the substrate, spacing between adjacent substrates, one or more dimensions of the coalescing unit. In certain embodiments, the mounting angle is within an angle range satisfying: L₁ sinθ<D; and L₂ tanθ<h, wherein L₁ is a length of the substrate in a vertical direction, D is an interval between adjacent substrates, L₂ is a horizontal length of the at least one coalescing unit, h is a height of the at least one coalescing unit from a lowermost end of the substrate, and θ is the inclination angle.

In some non-limiting embodiments, at least one coalescing unit comprises: a base coupled to the substrate; and a coalescing plate coupled to the base and extending therefrom at a coalescing plate angle relative to a surface of the substrate and configured to receive and coalesce the plurality of first vapor bubbles. The coalescing plate angle may be selected in consideration of at least one of a mounting angle of the substrate relative to the bottom surface of the housing, spacing between adjacent substrates, a generation rate of the plurality of first vapor bubbles, size, and an average size of the plurality of first vapor bubbles.

In some non-limiting embodiments, the coalescing plate comprises a vane structure, for example a vane structure having a regular pattern or an irregular pattern. In certain embodiments, the vane structure has a pattern selected from the group consisting of a flexible wire pattern, a ladder pattern, a mesh pattern, a comb pattern, and a wave pattern.

In some non-limiting embodiments, the coalescing plate comprises a solid plate.

In some non-limiting embodiments, each of the at least one coalescing unit may further comprise an angle adjustment mechanism coupling the coalescing plate to the base and permitting adjustment of the coalescing plate angle. In certain embodiments, each of the at least one coalescing unit may further comprise a biasing member configured to maintain the coalescing plate at a default coalescing plate angle; and a rotation limiter configured to restrict rotation of the coalescing plate beyond a certain angular range.

In some non-limiting embodiments, the at least one coalescing unit may be positioned at an upper end of at least one electronic component that vertically overlaps with an adjacent substrate.

In some non-limiting embodiments, the substrate may further comprise a blocking structure disposed between two or more of the plurality of electronic components and configured to inhibit convective transfer of heated coolant from a lower region to an upper region of the substrate.

According to an embodiment of the present disclosure, further provided is an electronic circuit board, the board comprising: a substrate; a plurality of electronic components mounted on the substrate; and at least one coalescing unit disposed on the substrate between two or more of the plurality of electronic components, the at least one coalescing unit configured to intercept and coalesce a plurality of first vapor bubbles generated by heating of coolant proximate to the plurality of electronic components into a second vapor bubble having a size greater than each of the plurality of first vapor bubbles.

In some non-limiting embodiments, the at least one coalescing unit may comprise a base coupled to the substrate, and a coalescing plate extending from the base at a coalescing plate angle, configured to intercept vapor bubbles rising from a lower electronic component and to coalesce the intercepted vapor bubbles into a larger coalesced vapor bubble that detaches from the coalescing plate upon reaching a threshold buoyancy.

In some non-limiting embodiments, the coalescing plate comprises a vane structure having a regular pattern or an irregular pattern. In certain embodiments, the coalescing plate comprises a vane structure having a pattern selected from the group consisting of a flexible wire pattern, a ladder pattern, a mesh pattern, a comb pattern, and a wave pattern. In certain embodiments, the coalescing plate comprises a solid plate.

In some non-limiting embodiments, each of the at least one coalescing unit may further comprise an angle adjustment mechanism coupling the coalescing plate to the base and permitting adjustment of the coalescing plate angle. In certain embodiments, each of the at least one coalescing unit may further comprise a biasing member configured to maintain the coalescing plate at a default coalescing plate angle, and a rotation limiter configured to restrict rotation of the coalescing plate beyond a certain angular range.

In some non-limiting embodiments, the substrate may further comprise a blocking structure disposed between two or more of the plurality of electronic components and configured to inhibit convective transfer of heated coolant to an upper region of the substrate.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a schematic diagram illustrating a system-level view of the entire immersion cooling apparatus.

FIG. 2 is a diagram illustrating one embodiment of an electronic circuit board comprising blocking structure positioned between electronic components.

FIG. 3 is a diagram illustrating a relationship between a coalescing plate angle of an electronic circuit board and a coalescing unit and an appropriate substrate mounting angle range for the substrates.

FIG. 4 is a diagram illustrating non-limiting multiple alternative embodiments of the coalescing plate structure.

FIG. 5A is a diagram illustrating one embodiment of a dynamic operation of the coalescing unit, depicting a default state of the dynamic operation.

FIG. 5B is a diagram illustrating one embodiment of the dynamic operation of the coalescing unit, depicting a rotation state of the dynamic operation.

### DETAILED DESCRIPTION

Hereinafter, embodiments or aspects will be described in detail with reference to the accompanying drawings. However, since various changes may be made in the embodiments or aspects, the scope of the patent disclosure is not limited or restricted by these embodiments or aspects. It should be understood that all modifications, equivalents, and alternatives for the embodiments or aspects are comprised in the scope of the present disclosure. For example, it is to be understood that the present disclosure may assume various alternative variations and step sequences, except where expressly specified to the contrary. It is also to be understood that the specific devices and processes illustrated in the attached drawings, and described in the following detailed description, are simply exemplary and non-limiting embodiments or aspects of the disclosed subject matter. Hence, specific dimensions and other physical characteristics related to the embodiments or aspects disclosed herein are not to be considered as limiting.

No aspect, component, element, structure, act, step, function, instruction, and/or the like used herein should be construed as critical or essential unless explicitly described as such. Also, as used herein, the articles “a” and “an” are intended to include one or more items and may be used interchangeably with “one or more” and “at least one.” Furthermore, as used herein, the term “set” is intended to include one or more items (e.g., related items, unrelated items, a combination of related and unrelated items, and/or the like) and may be used interchangeably with “one or more” or “at least one.” Where only one item is intended, the term “one” or similar language is used. Also, as used herein, the terms “comprise”, “comprises”, “comprising”, “include”, “includes”, “including”, “has,” “have,” “having,” or the like are intended to be open-ended terms. Further, the phrase “based on” is intended to mean “based at least partially on” unless explicitly stated otherwise. In addition, reference to an action being “based on” a condition may refer to the action being “in response to” the condition. For example, the phrases “based on” and “in response to” may, in some non-limiting embodiments or aspects, refer to a condition for automatically triggering an action (e.g., a specific operation of an electronic device, such as a computing device, a processor, and/or the like).

It will be understood that when a component is described as being “connected,” “combined” or “coupled” to another component, the component may be directly connected or coupled to the another component, but it may be “connected,” “combined” or “coupled” to the another component by an intervening another component that may be present.

Also, as used herein, the terms “upper”, “upward”, “lower”, “bottom”, “side”, “right”, “left” or the like are used with reference to the respective positions or orientations, respectively, shown in the drawings for representing a positional relationship in the given context. Specifically, the terms “upper”, “lower”, and “bottom” refer to a height direction perpendicular to a planar directions. In a three-dimensional Cartesian coordinate system, the planar directions corresponds to the X direction and to the Y direction, and the height direction to the Z direction. For instance, the Z direction may represent a vertical direction in which bubbles may move upward.

Further, in describing the components of the embodiment or aspect, the meaning of “or” may mean each of the components, may mean two or more of the components, or may mean all of the components. For example, it should be understood that the expressions “a, b or c” represent any one of “a,” “b,” “c,” “a and b,” “a and c,” “b and c,” and “a, b and c.”

Components included in one embodiment or aspect and components having common functions will be described using the same name in other embodiments or aspects. The description given in one embodiment or aspect may be applied to other embodiments or aspects and therefore will not be described in detail within the overlapping range, unless there is a contrary description.

The device and/or ‘data’ processed by the device may be expressed in terms of ‘information’. Here, the information may be used as a concept comprising the data.

The invention relates to an immersion cooling apparatus and electronic circuit boards designed to address heat dissipation challenges in high-performance computing environments.

The immersion cooling apparatus 100 according to embodiments of the present disclosure provides significant advantages over conventional immersion cooling systems by incorporating at least one coalescing unit on the substrate. The at least one coalescing unit intercepts and coalesces first vapor bubbles generated by heat from the plurality of electronic components into a coalesced vapor bubble that detaches upon reaching threshold buoyancy. By preventing vapor adhesion to adjacent substrates, the at least one coalescing unit inhibits unwanted convective heat transfer, avoids vapor pocket or a thin vapor film formation, and eliminates hot-spot regions. These features improve cooling efficiency and reliability, resolve temperature imbalance among the plurality of substrates, and extend the lifespan of the plurality of electronic components, thereby reducing maintenance frequency and cost. These advantages are achieved through the structural and operational features described in detail below.

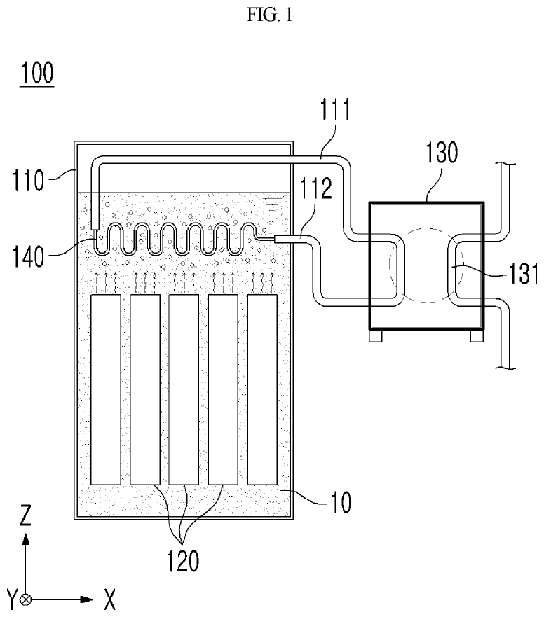

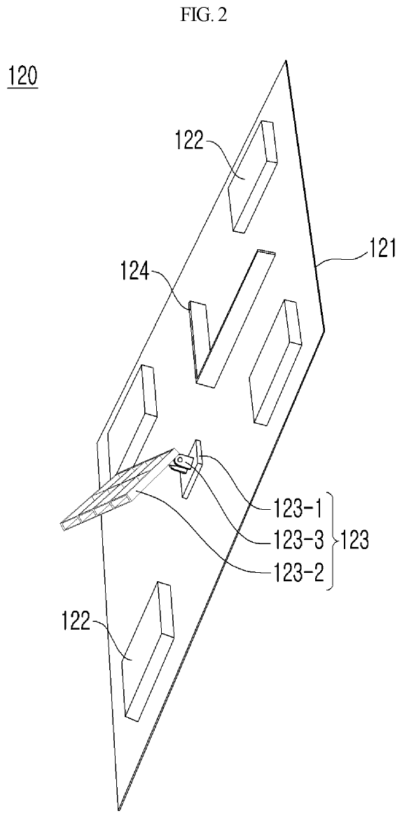

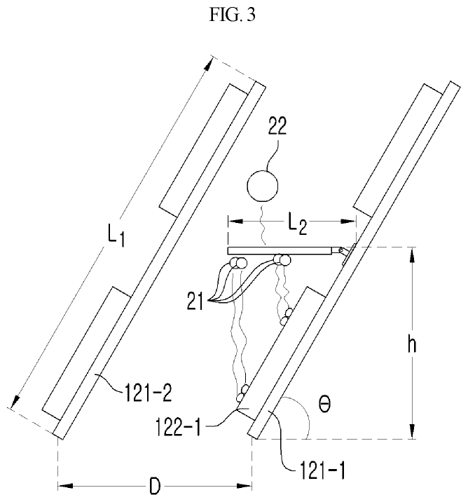

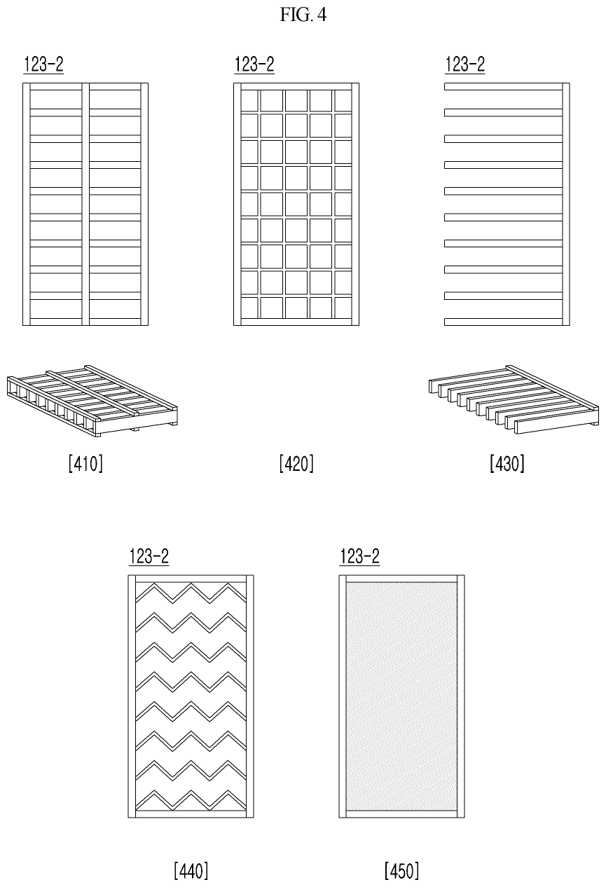

FIG. 1 is a schematic diagram illustrating a system-level view of the entire immersion cooling apparatus, FIG. 2 is a diagram illustrating one embodiment of an electronic circuit board comprising blocking structure positioned between electronic components, FIG. 3 is a diagram for explaining a relationship between coalescing plate angle of an electronic circuit board and a coalescing unit and an appropriate substrate mounting angle range for the substrates, and FIG. 4 is a diagram illustrating non-limiting multiple alternative embodiments of the coalescing plate structure.

Referring to FIGS. 1 to 4, an immersion cooling apparatus 100 according to an embodiment of the present disclosure may have a two-phase configuration in a coolant (for example, a dielectric coolant or a dielectric fluid) undergoes a phase change during immersion cooling. For example, a liquid coolant 10 may absorb heat and vaporize into a gas (e.g., vapor bubbles), which may then be converted back to a liquid, e.g., by transferring heat to a condenser 140. The immersion cooling apparatus 100 may comprising a housing 110, a plurality of electronic circuit boards 120, a heat exchange device 130, and a condenser 140.

The housing 110 may contain or store the liquid coolant 10 therein. The shape or configuration of the housing 110 may be, for example, a rectangular parallel-piped shape. The housing 110 may have an internal space capable of accommodating a cooling target (e.g., the electronic circuit boards 120), and may contain the liquid coolant 10 in the internal space so as to immerse the plurality of cooling targets (e.g., the plurality of electronic circuit boards 120) therein.

At least one side (e.g., a top side or lid) of the housing 110 may be openable and closeable to allow insertion or removal of the cooling targets. The housing 110 may be sealed so that the coolant (whether in vapor (gas) or liquid form) does not leak.

The condenser 140 may be located in a liquid head space of the housing 110 in fluid connection with the heat exchange device 130 through a first pipe 111 and a second pipe 112. According to an embodiment, the condenser 140 removes heat from both liquid and vapor coolant (e.g., absorbs heat from the liquid coolant with which it is in direct fluid contact, such as shown in FIG. 1, but also from coolant in vapor form (e.g., fluid coolant 10 that have been vaporized by absorbing the heat of the electronic circuit boards 120). The coolant vapor may then be condensed back into a liquid and fall under gravity. Although the first pipe 111 and the second pipe 112 are illustrated and described separately in FIG. 1, this is for convenience of description, and the first pipe 111 and the second pipe 112 may be formed as a single pipe. Further, in some embodiments, a condenser 140 may be omitted or provided separately from or externally to the immersion cooling apparatus 100 shown in FIG. 1.

Although not depicted in the drawings, in such embodiments, the coolant vapor (or bubbles), having absorbed heat may be transported directly to the heat exchange device 130 positioned outside the housing through a first pipe. In the heat exchange device 130, vaporized coolant absorbs heat and is then returned to the inside of the housing through a second pipe.

In certain embodiments, such as shown in FIG. 1, the heat exchange device 130 is located outside the housing 110 and may be used in connection, for example, with the condenser to remove heat from the coolant. The heat exchange device 130 may absorb heat from a condenser refrigerant (e.g., a refrigerant that has absorbed heat from vaporized coolant) in the condenser 140. For example, in one embodiment, the heat exchange device 130 may absorb heat indirectly from refrigerant through a heat exchange medium 131 supplied separately.

As another example, in embodiments wherein the immersion cooling apparatus does not include a condenser, a primary heat exchange device may remove heat from the coolant in through the first pipe. The primary heat exchange device may recirculate the coolant, having been cooled in the condenser, into the housing through the second pipe.

The plurality of electronic circuit boards 120 may be disposed inside the housing 110. For example, the plurality of electronic circuit boards 120 may be disposed inside the housing 110 so as to be immersed in the liquid coolant 10. In certain embodiments, the plurality of electronic circuit boards 120 may be arranged inside the housing 110 to be spaced apart from each other in a first direction (e.g., an X-axis direction or a Y-axis direction) and at a certain mounting angle (substrate mounting angle) with respect to a lower surface (or a bottom surface) of the housing 110.

Each of the plurality of electronic circuit boards 120 (hereinafter, each electronic circuit board) may comprise a plurality of electronic components (e.g., integrated circuit (IC) chips). For example, the electronic circuit board may comprise Printed circuit board assembly (PCBA) or Circuit card assembly (CCA). Each electronic circuit board may comprise (e.g., install or dispose) a coalescing unit (e.g., a coalescer) at one side (e.g., between the electronic components) to limit and coalesce movement of a vapor droplet (e.g., a vapor droplet generated by nucleate boiling).

As illustrated in FIG. 2, each of the plurality of electronic circuit boards 120 may comprise a substrate 121 (e.g., a board such as a printed circuit board or PCB), a plurality of electronic components 122, and a coalescing unit 123.

The plurality of electronic components 122 may be disposed (or mounted) on the substrate 121. The substrate 121 may include a printed circuit board (PCB), a flexible printed circuit board (FPCB), and the like.

The plurality of electronic components 122 may be disposed on the substrate 121. The plurality of electronic components 122 may include, for example, a central processing unit (CPU), a graphics processing unit (GPU), a power module, a memory (e.g., a random access memory (RAM), a read only memory (ROM), etc.), a storage medium (e.g., a hard disk, a solid state drive (SSD), etc.), a communication module, and the like, for configuring a system (e.g., a server). The plurality of electronic components 122 may generate heat during operation of the system, and the generated heat may be absorbed by the coolant 10, causing the coolant to vaporize and form vapor bubbles through a nucleate boiling phenomenon. Heat generation among the plurality of electronic components 122 may vary depending on performance characteristics. For example, the higher the integration density and processing speed of the plurality of electronic components 122, the greater the generation rate and size of first vapor bubbles.

At least one coalescing unit 123 may be disposed between the plurality of electronic components 122. For example, the at least one coalescing unit 123 may be disposed at an upper end of an electronic component that is vertically aligned with an adjacent substrate. In this configuration, the at least one coalescing unit 123 intercepts first vapor bubbles 21 that would otherwise rise in an upward direction along a rising path toward the adjacent substrate 121. The at least one coalescing unit 123 coalesces the first vapor bubbles 21 into a coalesced vapor bubble (i.e., a second vapor bubble 22) that detaches upon reaching threshold buoyancy, thereby preventing vapor adhesion to the adjacent substrate 121. The coalescing unit 123 may be formed integrally with the substrate 121, or may be formed as a separate structure and then attached or coupled or mounted to the substrate 121.

According to an embodiment, the coalescing unit 123 may intercept a vapor bubble 21 generated by the heating of the coolant proximate to the electronic components 122. In other words, as illustrated in FIG. 3, the coalescing unit 123 may prevent the vapor bubble 21 generated on the surface of a first substrate 121-1, among the plurality of substrates 121, from rising and becoming attached to a second substrate 121-2. When heat is generated in a first electronic component 122-1 of the first substrate 121-1, at least one vapor bubble (such as a plurality of first vapor bubbles) 21 may be generated on a surface of the first electronic component 122-1 (or a surface of a heat dissipator (e.g., a heat sink) covering the surface of the first electronic component 122-1 for heat dissipation) by a nucleate boiling phenomenon. The plurality of generated first vapor bubbles 21 may rise (or float) by a floating force (e.g., the combined effect of the buoyancy of the first vapor bubble 21 and drag force from the flow of the coolant 10). The first vapor bubble 21 rising in the vertical direction may adhere (or accumulate) to the coalescing unit 123 configured to intercept the path of a first vapor bubble 21. A plurality of first vapor bubbles 21 may then coalesce on the coalescing unit 123 until reaching a threshold, for example, upon reaching a threshold buoyancy, at which point the coalesced vapor bubble will detach. As used herein, “threshold buoyancy” is the point where buoyant force exceeds adhesive force.

According to an embodiment, the coalescing unit 123 may comprise a base 123-1 coupled (e.g., fixed) to the substrate 121 and a coalescing plate 123-2 extending from the base 123-1 configured to intercept and coalesce the first vapor bubbles 21 into a larger coalesced vapor bubble. The coalescing plate 123-2 may be coupled (e.g., fixed) to the base 123-1 at a particular angle relative to the surface of the substrate (herein “coalescing plate angle”). The coalescing plate angle may be an angle selected (e.g., optimized) in consideration of spacing between the substrates 121 (hereinafter, a substrate spacing) and/or a mounting angle of the substrate 121 relative to the bottom surface of the housing, so that the rising first vapor bubbles 21 can easily adhere to the coalescing plate. The coalescing plate angle may be further selected in consideration of generation rate of the plurality of first vapor bubbles, an average size of the plurality of first vapor bubbles, and a flow velocity of the coolant. For example, as illustrated in FIG. 3, the coalescing plate angle may be an angle at which the coalescing plate 123-2 is horizontal to the bottom surface of the housing 110.

According to some embodiments, as illustrated in FIG. 2, the coalescing unit 123 may further comprise an angle adjustment mechanism (e.g., a hinge) 123-3 permitting adjustment of the coalescing plate angle between the base 123-1 and the coalescing plate 123-2. The angle adjustment mechanism 123-3 may be used to adjust the coalescing plate angle between the base 123-1 and the coalescing plate 123-2 under the control of the immersion cooling apparatus 100 (or a user). The angle between the base 123-1 and the coalescing plate 123-2 may be adjusted or selected based on one or more of the generation rate of the plurality of first vapor bubbles, the average size of the plurality of first vapor bubbles, flow velocity of the coolant 10), the mounting angle of the substrate 121, and/or the substrate spacing.

According to an embodiment, the coalescing plate angle between the base 123-1 and the coalescing plate 123-2 may be selected automatically by the immersion cooling apparatus 100 (e.g., using a drive module (e.g., a motor) (not shown) that controls driving (e.g., rotation) of the angle adjustment mechanism 123-3). For example, sensing components installed within the immersion cooling apparatus 100 may check temperatures or a temperature distribution of electronic components of the substrate 121 using a temperature sensor, and appropriate adjust the coalescing plate angle between the base 123-1 and the coalescing plate 123-2 according to the checked temperatures or temperature distribution. In certain embodiments, the immersion cooling apparatus 100 may be configured or programmed to calculate a particular coalescing plate angle based on previous mapping of checked temperatures or temperature distributions, and adjust the coalescing plate angle between the base 123-1 and the coalescing plate 123-2 appropriate to the mapped coalescing plate angle. According to some embodiments, the immersion cooling apparatus 100 may calculate the coalescing plate angle using an Artificial Intelligence (AI) model. The AI model may include, but is not limited to, a regression model that is programmed to learn a correlation between an input variable (e.g., temperature (or temperature distribution)) and an output variable (e.g., angle) using training data. The AI model may be trained by further considering at least one of a generation rate of the plurality of first vapor bubbles, the average size of the plurality of first vapor bubbles, flow velocity of the coolant 10), mounting angle of the substrate 121, and the substrate spacing as an input variable.

According to some embodiments, the coalescing plate angle between the base 123-1 and the coalescing plate 123-2 may also be manually adjusted by a user.

As illustrated in FIG. 3, vapor bubbles that have coalesced to form a second vapor bubble of a threshold size 22 detach from the coalescing unit 123 and continue rising in the vertical direction. Even if the second vapor bubble 22 comes into contact with a second substrate 121-2 (e.g., a rear surface of the second substrate 121-2) while rising again, it will not adhere to the second substrate 121-2 due to a floating force (e.g., the combined effect of the buoyancy of the second vapor bubble and drag force from the flow of the coolant 10). In particular, the floating force of the second vapor bubble 22 is greater than the adhesive force of the second vapor bubble 22 as it contacts the second substrate 121-2.

In embodiments wherein the mounting angles of the first substrate 121-1 and the second substrate 121-2 are greater than or equal to a predetermined level (e.g., when the substrate 121 gradually moves from a vertical state to a horizontal state), the second vapor bubble 22 may not escape into a space between the first substrate 121-1 and the second substrate 121-2, and may adhere to the second substrate 121-2 or remain in the space between the first substrate 121-1 and the second substrate 121-2.

A mounting angle (θ) of the first substrate 121-1 and the second substrate 121-2 at which the second vapor bubble 22 can smoothly rise to an upper space of the housing 110 (e.g., a position of the condenser 140) may be selected (calculated) using <Equation 1> and <Equation 2> below.

L₁sinθ<D <Equation 1>

L₂tanθ<h <Equation 2>

In <Equation 1> and <Equation 2>, “L₁” denotes a length of the substrate 121 (e.g., a length in the height direction (Z-axis direction)), “D” denotes a substrate interval, “L₂” denotes a traverse length of the coalescing unit 123 (e.g., a horizontal length from a surface of the substrate 121 where the base 123-1 is installed to an end of the coalescing plate 123-2), and “h” denotes a height of the coalescing unit 123 (e.g., a height from a lowermost end of the substrate 121 to the coalescing unit 123).

According to an embodiment, the coalescing unit 123 (e.g., the coalescing plate 123-2) may have a structure configured to coalesce a plurality first vapor bubbles 21 into a coalesced vapor bubble (herein a second vapor bubble) until the second vapor bubble 22 reaches threshold buoyancy. According to an embodiment, the coalescing plate 123-2 comprises a vane structure having a regular pattern or an irregular pattern. For example, as illustrated in FIG. 4, the coalescing plate 123-2 of the coalescing unit 123 may comprise a vane structure having a ladder pattern 410, a mesh pattern 420, a comb pattern 430, or a wave pattern 440. According to some embodiments, the coalescing plate 123-2 may comprise a vane structure having a flexible wire pattern. The threshold buoyancy, which depends on a threshold size of the second vapor bubble 22 (or a rising speed of the second vapor bubble 22) may be dictated by the pattern (e.g., spacing between adjacent vanes) of the vane structure. According to some embodiments, the coalescing plate 123-2 comprises a solid plate 450, for example, absent any vane pattern.

Although FIGS. 2 and 3 illustrate and describe one coalescing unit 123 mounted on each substrate 121, each substrate 121 may comprise a plurality of coalescing units 123 positioned between respective electronic components 122. On the other hand, a coalescing unit may not be installed on all substrates 121. For example, in embodiments wherein the substrates 121 are arranged in a horizontal direction (e.g., an X-axis direction) and the substrates 121 are mounted at an angle to be inclined to the right, the leftmost substrate (e.g., the second substrate 121-2 in FIG. 3) may not contain a coalescing unit.

The immersion cooling apparatus 100 described above comprises at least one coalescing unit disposed on a rising path of vaporized coolant (e.g., dielectric coolant) that has absorbed heat from a plurality of electronic components 122. The at least one coalescing unit 123 coalesces a plurality of first vapor bubbles 21 into a coalesced vapor bubble (i.e., a second vapor bubble 22) that detaches upon reaching threshold buoyancy, thereby preventing a vapor adhesion phenomenon in which vapor bubbles adhere to an adjacent substrate 121 positioned along the rising path. By preventing vapor adhesion, the immersion cooling apparatus 100 resolves temperature imbalance among electronic components during immersion cooling, improves reliability, and improves cooling efficiency. In addition, the lifespan of the electronic components 122 is extended by effectively removing heat therefrom. As the lifespan of the electronic components is extended, a frequency of maintenance may decrease (or a maintenance cycle may increase) and/or a cost of maintenance may decrease.

As illustrated in FIG. 2, each substrate 121 may further comprise a blocking structure 124 (e.g., a baffle, rib, wall, or the like) that blocks or restricts the movement or flow of the coolant 10 between the plurality of electronic components 122, thereby inhibiting convective transfer of heat via the coolant 10 between adjacent electronic components 122 on the same substrate 121. Whereas the coalescing unit 123 intercepts vapor bubbles 21 rising from the plurality of electronic components 122, the blocking structure 124 inhibits convective transfer of heated liquid dielectric coolant 10 between vertically aligned electronic components 122 on the same substrate 121. The blocking structure 124 may be positioned between a lower electronic component 122 and an upper electronic component 122 that are disposed along a vertical axis such that liquid coolant heated by the lower electronic component 122 would otherwise flow toward the upper electronic component along a rising path of. By blocking this flow, the blocking structure 124 prevents the heated liquid coolant 10 from decreasing the cooling efficiency of the upper electronic component.

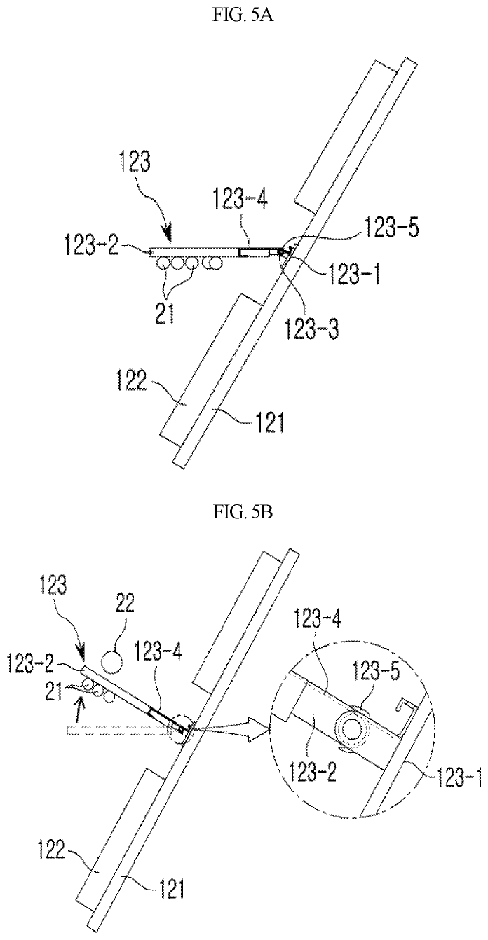

FIG. 5A is a diagram illustrating one embodiment of a dynamic operation of the coalescing unit, depicting a default state of the dynamic operation, FIG. 5B is a diagram illustrating one embodiment of the dynamic operation of the coalescing unit, depicting a rotation state of the dynamic operation.

Referring to FIGS. 5A and 5B, the coalescing unit 123 according to an embodiment of the present disclosure may comprise a base 123-1, a coalescing plate 123-2, an angle adjustment mechanism 123-3, a biasing member (e.g., an elastic member) 123-4, and a rotation limiter (e.g., stopper or catching projection) 123-5.

A detailed description of the base 123-1, the coalescing plate 123-2, and the angle adjustment mechanism 123-3 has been described with reference to FIGS. 1 to 4, and thus will not be repeated.

The biasing member 123-4 may maintain the angle adjustment mechanism (e.g., a hinge) 123-3 at a default angle (e.g., at a default coalescing plate angle).

The rotation limiter (e.g., a stopper or a catching projection) 123-5 may restrict rotation of the coalescing plate 123-2 to within a preselected angular range. For example, the rotation limiter 123-5 may inhibit rotation range of the coalescing plate 123-2 to avoid collision of the coalescing plate 123-2 with another substrate (or an electronic component) when rotated by the buoyant force of a coalesced vapor bubble 22 that has reached its threshold buoyancy. By limiting rotation within the predetermined angular range, the rotation limiter 123-5 ensures that the coalescing plate 123-2 returns to its default position after the coalesced vapor bubble detaches, thereby maintaining the ability of the coalescing unit 123 to intercept subsequent first vapor bubbles 21.

According to an embodiment, the coalescing plate 123-2 of the coalescing unit 123 may be rotated about a rotation axis (e.g., a hinge axis) of the angle adjustment mechanism 123-3 by the buoyant force of a coalesced vapor bubble on the coalescing plate 123-2. For example, when first vapor bubbles 21 are generated due to heat from the electronic component 122 disposed on the substrate 121 while the coalescing plate 123-2 is in a default state, as shown in FIG. 5A. As additional first vapor bubbles 21 coalesce, the coalesced vapor bubble (i.e., the second vapor bubble 22) grows in size and buoyant force. When the buoyant force of the coalesced vapor bubble 22 exceeds a tension of the biasing member 123-4, the coalescing plate 123-2 may rotate upward about the rotation axis of the angle adjustment mechanism 123-3, as illustrated in FIG. 5B. The coalesced vapor bubble 22 detaches from the coalescing plate 123-2 upon reaching the threshold buoyancy, and the coalescing plate 123-2 returns to the default state by restoring force of the biasing member 123-4, thereby preparing the coalescing unit 123 to intercept subsequent first vapor bubbles 21.

According to some embodiments, the biasing member 123-4 may be replaceable. By replacing the biasing member 123-4 with a biasing member of different tension, the degree of coalescence (e.g., the size of the coalesced vapor bubble 22) at adhesion may be adjusted. For example, a biasing member 123-4 having a higher tension requires a greater buoyant force to rotate the coalescing plate 123-2, resulting in a larger coalesced vapor bubble at the point of reaching threshold buoyancy. Conversely, a biasing member 123-4 having a lower tension permits rotation at a lower buoyant force, resulting in a smaller coalesced vapor bubble at detachment. In this manner, the threshold buoyancy at which the coalesced vapor bubble detaches from the coalescing plate 123-2 may be tuned based on operating conditions or cooling requirements.

The immersion cooling apparatus according to an embodiment of the present disclosure may have improved (e.g., increased) cooling efficiency. For example, by intercepting first vapor bubbles with the coalescing unit, the immersion cooling apparatus prevents bubbles from adhering to an adjacent substrate, which would degrade heat dissipation from that substrate by forming vapor pockets or a thin vapor film between the coolant and adjacent substrate. By preventing vapor pocket or a thin vapor film formation between the substrate and the coolant, a heat transfer coefficient may be improved as the coolant and the substrate directly contact each other.

In addition, the immersion cooling apparatus of the present disclosure prevents generation of a hot-spot region caused by degraded heat dissipation in a localized region of a substrate where a vapor pocket or a thin vapor film would otherwise form due to a vapor adhesion phenomenon. As described above, by preventing vapor adhesion through the coalescing unit, the immersion cooling apparatus resolves temperature imbalance between substrates during immersion cooling and improves reliability. Furthermore, by extending the lifespan of electronic components, a frequency of maintenance may be decreased (or a maintenance cycle may be increased) and/or a cost of maintenance may be reduced.

The contents described above are merely examples applying the principles of the present disclosure, and other configurations may be further included without departing from the scope of the disclosed immersion cooling apparatus. For example, at least some of the various embodiments of the present disclosure described above may be combined.

What is claimed is:

1. An immersion cooling apparatus comprising:
a housing configured to store a dielectric coolant;
a plurality of electronic circuit boards disposed inside the housing and positioned to be immersed in the dielectric coolant; and
a heat exchange device in fluid connection with the housing and configured to remove heat absorbed by the dielectric coolant from the plurality of electronic circuit boards,
wherein at least one of the plurality of electronic circuit boards comprises:
a substrate;
a plurality of electronic components mounted on the substrate; and
at least one coalescing unit disposed on the substrate between two electronic components of the plurality of electronic components,
wherein the at least one coalescing unit configured to intercept and coalesce a plurality of first vapor bubbles generated by heating of the dielectric coolant proximate to the plurality of electronic components into a second vapor bubble having a size greater than each of the plurality of first vapor bubbles.

2. The immersion cooling apparatus of claim 1,
wherein the at least one second vapor bubble detaches from the at least one coalescing unit when a buoyant force acting on the at least one second vapor bubble exceeds an adhesive force between the at least one second vapor bubble and the at least one coalescing unit.

3. The immersion cooling apparatus of claim 2, wherein the buoyant force of the at least one second vapor bubble exceeds an adhesive force between the at least one second vapor bubble and an adjacent substrate such that the at least one second vapor bubble does not adhere to the adjacent substrate upon contact therewith.

4. The immersion cooling apparatus of claim 1, wherein the plurality of electronic circuit boards are arranged within the housing at a mounting angle relative to a bottom surface of the housing.

5. The immersion cooling apparatus of claim 4, wherein the mounting angle is selected based on at least one of length of the substrate, spacing between adjacent substrates, and one or more dimensions of the coalescing unit.

6. The immersion cooling apparatus of claim 1, wherein the at least one coalescing unit comprises:
a base coupled to the substrate; and
a coalescing plate coupled to the base and extending therefrom at a coalescing plate angle relative to a surface of the substrate and configured to receive and coalesce the plurality of first vapor bubbles.

7. The immersion cooling apparatus of claim 6, wherein the coalescing plate angle is selected in consideration of at least one of a mounting angle of the substrate relative to the bottom surface of the housing, spacing between the adjacent substrates, an average size of the plurality of first vapor bubbles, a generation rate of the first vapor bubbles, and a flow velocity of the coolant.

8. The immersion cooling apparatus of claim 6, wherein the coalescing plate comprises a vane structure having a pattern selected from the group consisting of: a flexible wire pattern, a ladder pattern, a mesh pattern, a comb pattern, and a wave pattern.

9. The immersion cooling apparatus of claim 6, wherein the coalescing plate comprises a solid plate.

10. The immersion cooling apparatus of claim 6, wherein each of the at least one coalescing unit further comprises an angle adjustment mechanism coupling the coalescing plate to the base and permitting adjustment of the coalescing plate angle.

11. The immersion cooling apparatus of claim 10, wherein each of the at least one coalescing unit further comprises:
a biasing member configured to maintain the coalescing plate at a default coalescing plate angle; and
a rotation limiter configured to restrict rotation of the coalescing plate beyond a certain angular range.

12. The immersion cooling apparatus of claim 1, wherein the at least one coalescing unit is positioned at an upper end of at least one electronic component that vertically overlaps with an adjacent substrate.

13. The immersion cooling apparatus of claim 1, wherein the substrate further comprises a blocking structure disposed between two or more of the plurality of electronic components and configured to inhibit convective transfer of heated coolant from a lower region to an upper region of the substrate.

14. An electronic circuit board comprising:
a substrate;
a plurality of electronic components mounted on the substrate; and
at least one coalescing unit disposed on the substrate between two or more of the plurality of electronic components, the at least one coalescing unit configured to intercept and coalesce a plurality of first vapor bubbles generated by heating of dielectric coolant proximate to the plurality of electronic components into a second vapor bubble having a size greater than each of the plurality of first vapor bubbles.

15. The electronic circuit board of claim 14, wherein the at least one coalescing unit comprises:
a base coupled to the substrate; and
a coalescing plate extending from the base at a coalescing plate angle, configured to intercept vapor bubbles rising from a lower electronic component and to coalesce the intercepted vapor bubbles into a larger coalesced vapor bubble that detaches from the coalescing plate upon reaching a threshold buoyancy.

16. The electronic circuit board of claim 15, wherein the coalescing plate comprises a vane structure having a pattern selected from the group consisting of: a flexible wire pattern, a ladder pattern, a mesh pattern, a comb pattern, and a wave pattern.

17. The electronic circuit board of claim 15, wherein the coalescing plate comprises a solid plate.

18. The electronic circuit board of claim 15, wherein each of the at least one coalescing unit further comprises an angle adjustment mechanism coupling the coalescing plate to the base and permitting adjustment of the coalescing plate angle.

19. The electronic circuit board of claim 18, wherein each of the at least one coalescing unit further comprises:
a biasing member configured to maintain the coalescing plate at a default coalescing plate angle; and
a rotation limiter configured to restrict rotation of the coalescing plate beyond a certain angular range.

20. The electronic circuit board of claim 14, wherein the substrate further comprises a blocking structure disposed between two or more of the plurality of electronic components and configured to inhibit convective transfer of heated coolant to an upper region of the substrate.
